(19) United States
(12) Patent Application Publication
(10) Pub. No.: US 2025/0022990 A1
(43) Pub. Date: Jan. 16, 2025

(54) DISPLAY DEVICE USING SEMICONDUCTOR LIGHT-EMITTING ELEMENT

(71) Applicant: LG ELECTRONICS INC., Seoul (KR)

(72) Inventors: Seungmi BAEK, Seoul (KR); Gunyoung HONG, Seoul (KR); Younggil YOO, Seoul (KR); Minsung KIM, Seoul (KR); Kyungpil KIM, Seoul (KR); Bokyung KANG, Seoul (KR)

(73) Assignee: LG ELECTRONICS INC., Seoul (KR)

(21) Appl. No.: 18/715,672

(22) PCT Filed: Jan. 10, 2022
(86) PCT No.: PCT/KR2022/000363

§ 371 Date: May 31, 2024

(51) Int. Cl. H01L 33/50; H01L 25/075

(52) U.S. Cl. CPC H01L 33/505; H01L 25/0753

(57) ABSTRACT

The present invention is applicable to display device-related technical fields and relates to, for example, a display device using a micro light-emitting diode (LED). The present invention may comprise: a substrate; partition walls which are arranged on the substrate to define a plurality of hexagonal unit pixel areas forming a honeycomb shape; semiconductor light-emitting elements each of which is disposed in each of the unit pixel areas to form each unit pixel; color conversion layers which convert light emitted from the semiconductor light-emitting elements into colors corresponding to the respective unit pixel areas; a porous layer which is disposed on the partition walls and in which a plurality of through-holes are formed; and color filter layers which are disposed on the porous layer.

### TECHNICAL FIELD

The present disclosure is applicable to a technical field related to a display device, and for example, to a display device using a micro Light Emitting Diode (LED).

### BACKGROUND ART

Recently, display devices having excellent characteristics such as thinness, flexibility, and the like have been developed in the field of display technology. Currently commercialized main displays are represented by a Liquid Crystal Display (LCD) and an Organic Light Emitting Diode (OLED) display.

Meanwhile, a Light Emitting Diode (LED) is a semiconductor light emitting device that is well known to convert a current into light, and has been used as a display image light source of an electronic device such as an information communication device together with a green LED of an GaP: N series at the beginning of the commercialization of a red LED using a GaAsP compound semiconductor in 1962.

Recently, such a light emitting diode (LED) tends to have a small size gradually and is manufactured as a micrometer-sized LED, thereby being used as a pixel of a display device.

Such micro LED technology has low power, high luminance, and high reliability compared to other display devices/panels, and is applicable to flexible devices. Therefore, many ongoing efforts are made to such technology by research institutes and companies.

Meanwhile, a display device using an LED may have a rectangular unit pixel area. In some cases, the display device using the LED may have a unit pixel area of a honeycomb structure.

However, a diffusion layer is usually disposed in the unit pixel area of the honeycomb structure using the LED of the related art so that crosstalk of light emitted from the LED is generated, thereby being unsuitable for a display device using a micro LED.

Accordingly, a display device having high efficiency is required while a unit pixel area of a honeycomb structure is applied to a display device using a micro LED.

### DISCLOSURE

### Technical Tasks

One technical task of the present disclosure to provide a display device using a semiconductor light emitting device capable of preventing overlapping of color converted light generated in each light emitting device.

Another technical task of the present disclosure is to provide a display device using a semiconductor light emitting device capable of improving color purity of light emitted from each unit pixel area.

Another technical task of the present disclosure is to provide a display device using a semiconductor light emitting device capable of reducing the number of processes and material costs.

Another technical task of the present disclosure is to provide a display device using a semiconductor light emitting device, which may have excellent light uniformity.

Further technical task of the present disclosure is to provide a display device using a semiconductor light emitting device capable of providing an optimal condition for exhibiting excellent luminance in a pixel structure of a honeycomb shape.

### Technical Solutions

In a first technical aspect of the present disclosure, provided is a display device including a substrate, a partition wall located on the substrate and defining a plurality of hexagonal unit pixel areas to form a honeycomb shape, a semiconductor light emitting device located in each of the unit pixel areas to form each unit pixel, a color conversion layer converting light emitted from the semiconductor light emitting device into a color corresponding to each of the unit pixel areas, a porous layer located on the partition wall and having a plurality of through-holes, and a color filter layer located on the porous layer.

Each of the unit pixel areas may be partitioned by the partition wall to have a predetermined region.

The color conversion layer may be located in the partitioned unit pixel area.

The color conversion layer may be located at a predetermined distance from the semiconductor light emitting device on the partition wall.

The partition wall may act as a black matrix.

The porous layer may prevent lights emitted from the unit pixel areas from being mixed.

The through-hole of the porous layer may be formed in a direction of connecting the unit pixel area and the color filter.

The porous layer may include an Anodized Aluminum Oxide (AAO) layer.

The color filter layer may include a color filter corresponding to a color of each of the unit pixel areas.

The color filter layer may include a yellow filter corresponding to a region of a color of part of the unit pixel areas.

The yellow filter may be located on a red pixel area and a green pixel area among the unit pixel areas.

In a second technical aspect of the present disclosure, provided is a display device including a wiring substrate, a partition wall located on the substrate and defining a plurality of hexagonal unit pixel areas, a semiconductor light emitting device located in each of the unit pixel areas to form each unit pixel, a porous layer located on the partition wall to prevent mixing of lights emitted from the unit pixel areas, a color conversion layer located between the partition wall and the porous layer to convert the light emitted from the semiconductor light emitting device to a color related to each of the unit pixel areas, and a color filter layer located on the porous layer.

The porous layer may include a plurality of through-holes formed in a direction of connecting the unit pixel area and the color filter.

A plurality of the hexagonal unit pixel areas may form a honeycomb shape.

### Advantageous Effects

According to an embodiment of the present disclosure, the following effects are obtained.

First, according to an embodiment of the present disclosure, since a pixel structure defined by a partition wall capable of acting as a black matrix is arranged in a honeycomb shape, the overlap of a color converted light generated from each light emitting device may be prevented (i.e., crosstalk prevention).

In addition, the straightness of light emitted from each unit pixel area is improved such that the light emitted from each light emitting device is localized without being mixed with each other and emitted to reach a color filter layer, thereby improving color purity.

In addition, a dielectric or black matrix material for forming a partition wall may be reduced. Therefore, the number of processes and material costs may be significantly reduced.

In addition, when a pixel structure is a honeycomb structure, light uniformity in the same space may be further improved.

As such, when the same size light source and the same area are occupied, a honeycomb structure may have better light uniformity than that of a square structure.

In addition, an optimal condition in which an optimal luminance may be exhibited in a pixel structure of a honeycomb shape may be provided.

Furthermore, according to another embodiment of the present disclosure, there are also additional technical effects not mentioned herein. Those skilled in the art may understand them through the application of the specification and drawings.

### DESCRIPTION OF DRAWINGS

FIG. 1 is a layout illustrating unit pixel areas of a display device using a semiconductor light emitting device according to an embodiment of the present disclosure.

FIG. 2 is a schematic cross-sectional diagram illustrating a display device using a semiconductor light emitting device according to a first embodiment of the present disclosure.

FIGS. 3 to 5 are conceptual diagrams illustrating features of a hexagonal unit pixel area of a display device using a semiconductor light emitting device according to an embodiment of the present disclosure.

FIG. 6 is a conceptual diagram illustrating a first arrangement example of a partition wall of a display device using a semiconductor light emitting device according to an embodiment of the present disclosure.

FIG. 7 is a conceptual diagram illustrating a second arrangement example of a partition wall of a display device using a semiconductor light emitting device according to an embodiment of the present disclosure.

FIG. 8 is a perspective diagram illustrating an example of a porous layer of a display device using a semiconductor light emitting device according to an embodiment of the present disclosure.

FIG. 9 is a photograph showing an example of a porous layer of a display device using a semiconductor light emitting device according to an embodiment of the present disclosure.

FIG. 10 is a schematic cross-sectional diagram illustrating a display device using a semiconductor light emitting device according to a second embodiment of the present disclosure.

FIG. 11 is a schematic cross-sectional diagram illustrating a display device using a semiconductor light emitting device according to a third embodiment of the present disclosure.

FIG. 12 is a conceptual diagram illustrating a light conversion process of a display device using a semiconductor light emitting device according to a third embodiment of the present disclosure.

### BEST MODE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

The display device described herein is a concept including all display devices that display information with a unit pixel or a set of unit pixels. Therefore, the display device may be applied not only to finished products but also to parts. For example, a panel corresponding to a part of a digital TV also independently corresponds to the display device in the present specification. The finished products include a mobile phone, a smartphone, a laptop, a digital broadcasting terminal, a personal digital assistant (PDA), a portable multimedia player (PMP), a navigation system, a slate PC, a tablet, an Ultrabook, a digital TV, a desktop computer, and the like.

However, it will be readily apparent to those skilled in the art that the configuration according to the embodiments described herein is applicable even to a new product that will be developed later as a display device.

In addition, the semiconductor light emitting device mentioned in this specification is a concept including an LED, a micro LED, and the like, which may be used in a mixed manner.

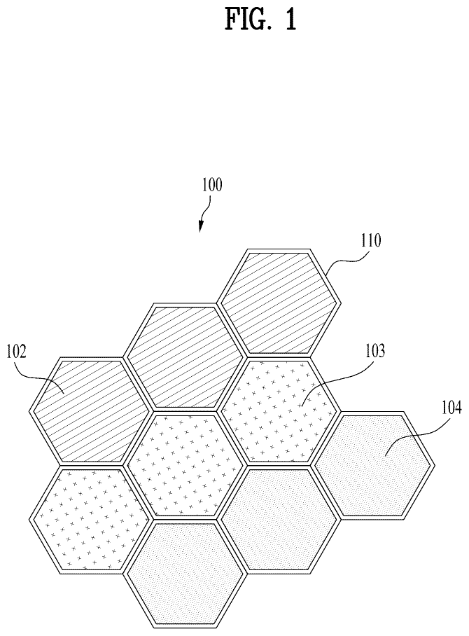

FIG. 1 is a layout illustrating unit pixel areas of a display device using a semiconductor light emitting device according to an embodiment of the present disclosure.

Referring to FIG. 1, a display device using a semiconductor light emitting device according to an embodiment of the present disclosure may have a pixel structure 100 including a plurality of hexagonal unit pixel areas 102, 103, and 104.

The unit pixel areas 102, 103, and 104 may be partitioned by a partition wall 110. The unit pixel areas 102, 103, and 104 may include a red pixel area 102, a green pixel area 103, and a blue pixel area 104.

The red pixel area 102 may emit red light as a sub-pixel. The green pixel area 103 may emit green light as a sub-pixel. Similarly, the blue pixel area 104 may emit blue light as a sub-pixel.

The unit pixel areas 102, 103, and 104 in the colors may be partitioned be being arranged in one direction. For example, the red pixel area 102, the green pixel area 103, and the blue pixel area 104 may be arranged in parallel to each other. In addition, the unit pixel areas 102, 103, and 104 may have a plurality of regular hexagonal shapes that are dense with each other. For example, the unit pixel areas 102, 103, and 104 may form a honeycomb shape.

A plurality of the hexagonal unit pixel areas 102, 103, and 104 may be formed by the partition wall 110. That is, the partition wall 110 may define a plurality of the hexagonal unit pixel areas having a honeycomb shape. As described above, each of the unit pixel area 102, 103, and 104, having a predetermined area, may be partitioned by the partition wall 110.

Features of the hexagonal unit pixel areas 102, 103, and 104 described with reference to FIG. 1 may be equally applied to the following respective embodiments. Further, detailed features of the unit pixel areas 102, 103, and 104 in the honeycomb shape will be described in detail later.

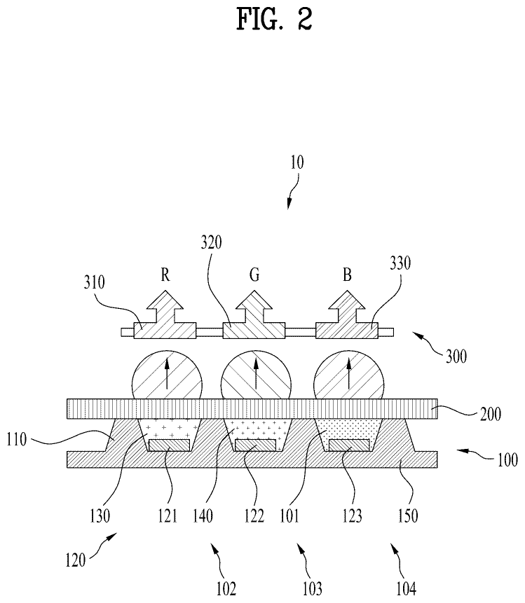

FIG. 2 is a schematic cross-sectional diagram illustrating a display device using a semiconductor light emitting device according to a first embodiment of the present disclosure.

A display device 10 according to the first embodiment of the present disclosure may include a pixel structure 100 including a substrate 150, a partition wall 110 defining a plurality of hexagonal unit pixel areas 102, 103, and 104 on the substrate 150, and a light emitting device 120 installed in each of the unit pixel areas 102, 103, and 104.

That is, the unit pixel areas 102, 103, and 104 may include a red pixel area 102, a green pixel area 103, and a blue pixel area 104. The light emitting device 120 may be a semiconductor Light Emitting Diode (LED).

The light emitting device 120 emitting blue light or ultraviolet light may be installed in each of the unit pixel areas 102, 103, and 104. For example, blue light emitting devices 121, 122, and 123 may be installed in the unit pixel areas 102, 103, and 104, respectively. Color conversion layers 130, 140, and 101 may be positioned on the blue light emitting devices 121, 122, and 123 to be converted to colors corresponding to the unit pixel areas 102, 103, and 104, respectively.

The semiconductor light emitting devices 121, 122, and 123 constituting a unit pixel may be micro LEDs having a size of several to several hundred micro-sizes. In some cases, the semiconductor light emitting devices 121, 122, and 123 may be mini LEDs, each having a size of several tens of times of a micro LED. Here, the mini LED may have a stack structure different from that of the micro LED as well as a size. Specifically, the mini LED may further include a growth substrate for growing a semiconductor layer.

When micro LEDs are used as the semiconductor light emitting devices 121, 122, and 123, the size of the micro LED may be approximately 20 μm or less.

As another example, a red light emitting device 121 may be installed in the red pixel area 102, a green light emitting device 122 may be installed in the green pixel area 103, and a blue light emitting device 123 may be installed in the blue pixel area 104.

As described above, the display device 10 may include the light emitting devices 120 (i.e., 121, 122, and 123) installed in the unit pixel areas 102, 103, and 104 to form each unit pixel.

Here, the substrate 150 may be a wiring substrate on which a wiring electrode (not shown) is arranged. In this case, each of the light emitting devices 121, 122, and 123 may be electrically connected to the wiring electrode. In addition, each of the light emitting devices 121, 122, and 123 may be electrically connected to a common electrode to be turned on by a current/voltage applied through the wiring electrode and the common electrode.

A Thin Film Transistor (TFT) may be connected to the wiring electrode to implement an Active Matrix (AM) type display device 10. For one example, the substrate 150 may be a TFT substrate. For another example, the substrate 150 may be a Passive Matrix (PM) type substrate.

In FIG. 2, the structure of the substrate 150 is schematically shown by being simplified. Hereinafter, a detailed configuration of the substrate 150 will be omitted.

A color conversion layer 130 or 140 may be provided in the unit pixel area 102/103/104 to convert light emitted from the light emitting device 121/122/123 into a color corresponding to the unit pixel area 102/103/104.

As an exemplary embodiment, the color conversion layer 130/140 may be provided in at least some portion of the unit pixel area 102/103/104.

For example, a red color conversion layer 130 may be located in the red pixel area 102, and a green color conversion layer 140 may be located in the green pixel area 103. Meanwhile, a light diffusing agent 101 may be provided in the blue pixel area 104. The light diffusing agent 101 may also be a kind of color conversion layer. That is, the color conversion layers 130, 140, and 101 may be located in the unit pixel areas 102, 103, and 104, respectively.

In an exemplary embodiment, the red color conversion layer 130 may include a red inorganic phosphor or a red Quantum Dot (QD) that converts blue light corresponding to a wavelength of 400 to 480 nm to a main wavelength band of 600 to 750 nm.

In an exemplary embodiment, the green color conversion layer 140 may include a green inorganic phosphor or a green Quantum Dot (QD) that converts blue light corresponding to a wavelength of 400 to 480 nm to a main wavelength band of 490 to 600 nm.

In the blue pixel area 104, the light diffusing agent 101 may include a metal oxide, for example, TiO₂.

In the present embodiment, the color conversion layers 130, 140, and 101 are filled in the unit pixel areas 102, 103, and 104, respectively. For example, the color conversion layers 130, 140, and 101 may be positioned to cover the semiconductor light emitting devices 121, 122, and 123 in the unit pixel areas 102, 103, and 104 partitioned by the partition wall 110, respectively.

A porous layer 200 having a plurality of through-holes formed therein may be disposed on the partition wall 110 defining the unit pixel areas 102, 103, and 104.

The porous layer 200 may prevent mixing of light emitted from the unit pixel areas 102, 103, and 104. That is, the porous layer 200 may prevent crosstalk, which is a phenomenon in which lights emitted from neighboring unit pixel areas are mixed together.

Light emitted from the semiconductor light emitting device 120 is generally radiated in all directions. Yet, in the present embodiment, since each of the light emitting devices 121, 122, and 123 is located inside the partition wall 110, the light emitted from the light emitting device 120 may be emitted through an area defined by an angle of the partition wall 110. That is, the light emitted from the light emitting device 120 may be emitted through a specific area partitioned by the partition wall 110.

The lights emitted from the light emitting devices 121, 122, and 123 through specific areas partitioned by the partition wall 110 may be mixed together with respect to the neighboring unit pixel areas 102, 103, and 104.

In this case, the porous layer 200 may prevent crosstalk, which is a phenomenon in which lights emitted from neighboring unit pixel areas are mixed with each other. In addition, the porous layer 200 may improve the straightness of light emitted from each of the unit pixel areas 102, 103, and 104.

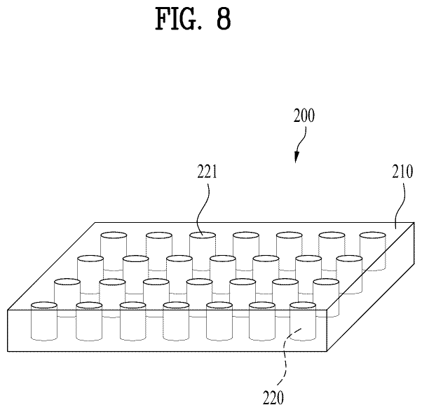

In an exemplary embodiment, the porous layer 200 may include a plurality of through-holes 220 (see FIG. 8) formed in an emission direction of light. For example, the through-hole 220 may be formed in a cylindrical shape. Light emitted from each of the light emitting devices 121, 122, and 123 may be emitted to a limited area through a plurality of the through-holes 220, thereby preventing a crosstalk phenomenon.

In an exemplary embodiment, the porous layer 200 may be an Anodized Aluminum Oxide (AAO) layer.

Referring to FIG. 2, owing to the porous layer 200, the lights emitted from the light emitting devices 121, 122, and 123 are localized and emitted without being mixed with each other. The porous layer 200 will be described in detail later.

A color filter layer 300 may be disposed on the porous layer 200. The color filter layer 300 may improve color purity of the light emitted from each of the unit pixel areas 102, 103, and 104.

The color filter layer 300 may include color filters 310, 320, and 330 corresponding to the colors of the unit pixel areas 102, 103, and 104, respectively. For example, the red color filter 310 may be located on the red pixel area 102, the green color filter 320 may be located on the green pixel area 103, and the blue color filter 330 may be located on the blue pixel area 104.

Referring to FIG. 2, the through-holes 221 of the porous layer 200 may be formed in a direction of connecting the unit pixel areas 102, 103, and 104 and the color filters 310, 320, and 330. As described above, the straightness of the light emitted from each of the unit pixel areas 102, 103, and 104 may be improved by the porous layer 200, and the lights emitted from the unit pixel areas 102, 103, and 104 may efficiently reach the color filters 310, 320, and 330 of the color filter layer 300 without overlapping each other, respectively.

Accordingly, the lights emitted from the unit pixel areas 102, 103, and 104 may be converted into respective colors R, G, and B by the color conversion layers 130, 140, and 101, respectively. The converted lights may reach the color filters 310, 320, and 330 of the color filter layer 300 without overlapping each other, thereby achieving an efficient pixel space arrangement.

In an exemplary embodiment, the partition wall 110 may act as a black matrix. For example, the partition wall 110 may be formed of a material in dark color, such as black, or may include a dark-colored material layer.

In addition, as described above, the unit pixel areas 102, 103, and 104 may form a honeycomb shape in which a hexagonal shape is repeated.

As described above, since the pixel structure 100 defined by the partition wall 110 serving as the black matrix is arranged in a honeycomb shape, the overlap of the color converted lights generated from the light emitting devices 121, 122, and 123 may be prevented (i.e., crosstalk prevention) and a pixel space arrangement more efficient than a pixel structure of a typical square arrangement may be available. In other words, the embodiment of the present disclosure may be referred to as an embodiment in which the straightness of light reaching the color filter layer 300 is focused.

In addition, the straightness of the light emitted from each of the unit pixel areas 102, 103, and 104 is improved so that the light emitted from each of the light emitting devices 121, 122, and 123 is localized without being mixed with each other and emitted to reach the color filter layer 300, thereby improving color purity.

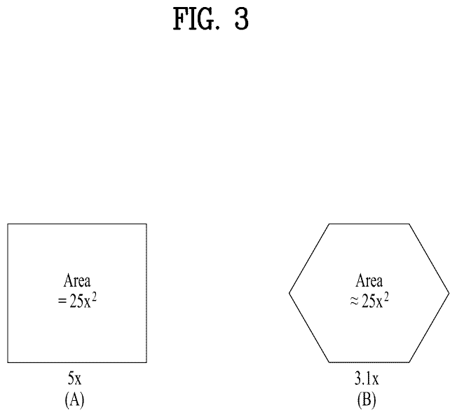

FIGS. 3 to 5 are conceptual diagrams illustrating features of a hexagonal unit pixel area of a display device using a semiconductor light emitting device according to an embodiment of the present disclosure.

As described above, the unit pixel areas 102, 103, and 104 may form a honeycomb shape in which a hexagonal shape is repeated.

Referring to FIG. 3, when the unit pixel area forms a square arrangement, if one side of the unit pixel area is 5×, a size of the corresponding area becomes 25×2. On the other hand, when one side of the unit pixel area forming a regular hexagonal shape according to the embodiment of the present disclosure is 3.1×, a size of the corresponding area may be approximately 25×2.

Therefore, when a light source of the same size is applied, the length of the partition wall 110 may correspond to 20× in the case of a square arrangement, and may correspond to 18.6× in the case of a regular hexagonal arrangement. Accordingly, the dielectric or black matrix material for forming the partition wall 110 may be reduced. In general, considering that a display includes a very large number of unit pixel areas, this difference may correspond to a large difference. Therefore, the number of processes and material costs may be significantly reduced.

In addition, when the pixel structure 100 has the honeycomb structure, light uniformity in the same space may be further improved.

As such, when the same size light source and the same area are occupied, the honeycomb structure may have better light uniformity than that of the square structure.

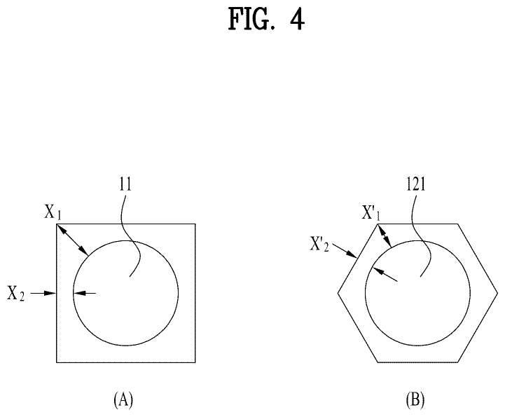

Referring to FIG. 4, when a light source is generally positioned at the center of a space, light density at each corner of a unit pixel area becomes the lowest.

In this case, in a square structure shown in FIG. 4 (A), a distance farthest from the light source is X₁ at the corner, and a distance closest to the light source corresponds to X₂ that is the distance from the light source to a center of a side. Meanwhile, in a regular hexagonal structure shown in FIG. 4 (B), a distance farthest from the light source is X′₁ at the corner, and a closest distance from the light source corresponds to X′₂, which is the distance from the center of a side. In this case, it may be seen that a difference between X′₁ and X′₂ is substantially reduced compared to the difference between X₁ and X₂.

In addition, in the square structure shown in FIG. 4 (A), there are four corners. In the regular hexagonal structure shown in FIG. 4 (B), there are six corers. Hence, light spreading efficiency may be better in the regular hexagonal structure. Accordingly, the light uniformity may be better in the regular hexagonal structure shown in FIG. 4 (B).

Mathematically solving this problem, when a light area reached over a predetermined luminance or higher is 19.6 x² in the same area 25x², a region having a low light density in the section is 5.4 x². In this case, in the structure of FIG. 4 (A), a region corresponding to each corner is 1.35x₂ (=5.4x²/4). In the structure of FIG. 4 (b), a region corresponding to each corner is 0.9x² (=5.4x²/6).

That is, the structure of FIG. 4 (B) is reduced by ⅔ compared to the structure of FIG. 4 (A), so that the light uniformity is better in the structure of FIG. 4 (B).

In other words, when ΔX=|X₁−X₂|>ΔX′=X′₁−X′₂, if the Δ value gets smaller, the converted light variation in the pixel becomes smaller. That is, the light uniformity may be better in the structure of FIG. 4 (B).

As described above, in the structure of FIG. 4 (B), the light uniformity of the individual light source (e.g., the light emitting device 120) is excellent, which means that more efficient spatial arrangement in light may be performed in the pixel structure 100 having the honeycomb structure.

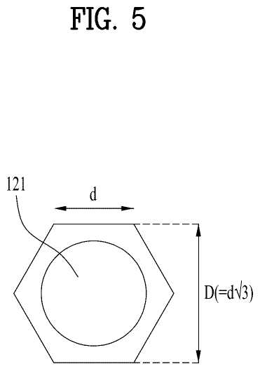

Referring to FIG. 5, a regular hexagonal unit pixel may be represented as a unit pixel area having a side length d and a width of D with respect to the light emitting device 121 as a light source. In this case, D may correspond to a width between a side and a side, not a width between a corner and a corner, that is, a width (=d\sqrt{3}) of the smallest size.

According to an embodiment of the present disclosure, when the light emitting device 121 as the light source is a micro LED, d and D may satisfy the following conditions, respectively, in consideration of the size range of the micro LED and the range of the size of the unit pixel area using the same.

$$1 μm \leq D \leq 200 μm \qquad ( Condition 1 )$$

$$0.58 μm \leq d \leq 115.47 μm \qquad ( Condition 2 )$$

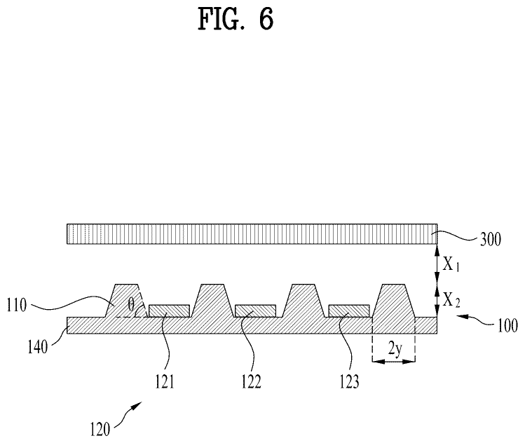

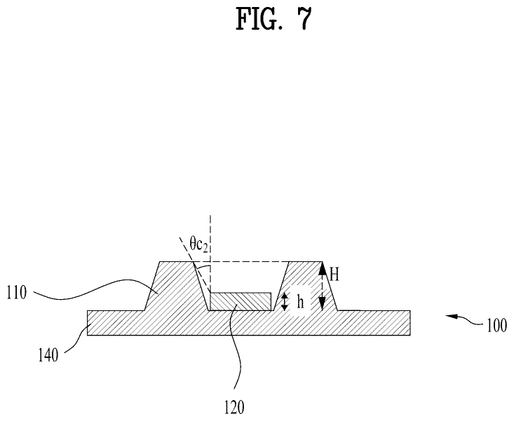

FIG. 6 is a conceptual diagram illustrating a first arrangement example of a partition wall of a display device using a semiconductor light emitting device according to an embodiment of the present disclosure. FIG. 7 is a conceptual diagram illustrating a second arrangement example of partition walls of a display device using a semiconductor light emitting device according to an embodiment of the present disclosure.

Referring to FIG. 6, a partition wall 110 may form a predetermined angle θ with a main plane of a substrate 150. Here, the corresponding angle amounts to an angle between a surface of the partition wall 110 in a unit device area and a plane of the substrate 150.

In addition, a height of the partition wall 110 is X₂, a distance between an upper end of the partition wall 110 and a structure on the partition wall 110, e.g., a color filter layers 300 is X₁, a long width of the partition wall 110 is 2y, and an angle of the partition wall 110 with respect to a vertical surface of the substrate 150 is θ_{c}. The, the angle θ_{c} of the partition wall 110 may satisfy a specific condition.

As an exemplary embodiment, if tan θ_{c}=(X₁+X₂)/y, θ>θ_{c} may be met.

Meanwhile, in an exemplary embodiment, if tan θc₂=y/(X₁+X₂−h) (here, θ_{c} may be denoted by θc₂), 90−θc₂<θ may be satisfied (Condition 3). Here, the thickness of a light emitting device 120 may be h.

Here, the angle θ_{c} (or θc₂) of the partition wall 110 is an influence factor of the opening area and enables luminance improvement management through the adjustment of 0. (or θc₂) (Condition 4).

In addition, referring to FIG. 7, when the thickness of the light emitting device 120 is h and the height of the partition wall 110 is H, the transmittance of the blue light may increase as H, which is the height of the partition wall, becomes closer to h, which is the thickness of the light emitting device 120

In this case, since a blue shielding layer for preventing transmission of blue light or an increase in the thickness H may be required, the thickness H of the partition wall 110 is preferably greater than the thickness h of the light emitting device 120 (H>h: Condition 5).

When at least one of the above conditions 3 to 5 is satisfied in the honeycomb pixel structure 100 having the structure including the substrate 150 and the partition wall 110 as described above, optimal luminance may be exhibited.

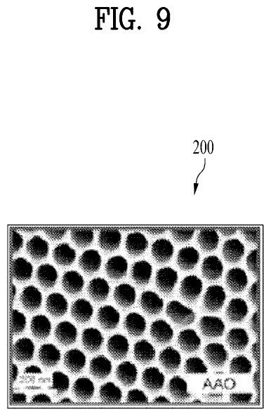

FIG. 8 is a perspective diagram illustrating an example of a porous layer of a display device using a semiconductor light emitting device according to an embodiment of the present disclosure. FIG. 9 is a photograph showing an example of a porous layer of a display device using a semiconductor light emitting device according to an embodiment of the present disclosure.

As described above, the porous layer 200 having a plurality of through-holes may be disposed on the partition wall 110 defining the unit pixel areas 102, 103, and 104.

The porous layer 200 may include a matrix 210 and a plurality of through-holes 220 formed in the matrix 210 to be parallel to each other in an emission direction of light. For example, the through-hole 220 may be formed in a cylindrical shape. In addition, the through-hole 220 may include a circular opening 221.

Light emitted from each of the light emitting devices 121, 122, and 123 may be emitted to a limited area through a plurality of the through-holes 220, thereby preventing a crosstalk phenomenon.

In an exemplary embodiment, the porous layer 200 may be an Anodized Aluminum Oxide (AAO) layer. The porous layer 200 may have a thickness of 1 μm or less.

The AAO ACL layer has a nanoporous surface to change an effective refractive index between a nanoporous structure and air, thereby reducing reflection and inducing straightness of light.

Therefore, according to an embodiment of the present disclosure, an anti-reflection effect may be obtained by using the partition wall 110 capable of performing a black matrix function. In addition, crosstalk may be prevented by inducing the straightness of light through the porous layer 200 implemented as the AAO layer.

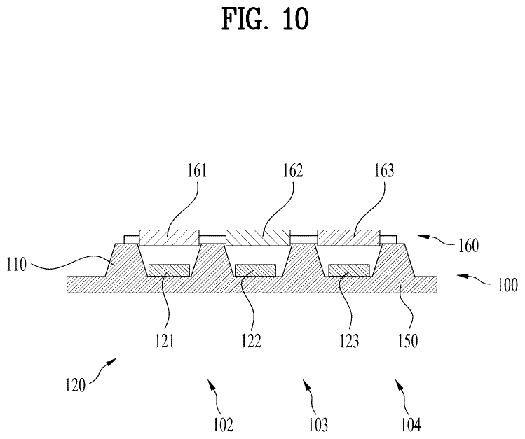

FIG. 10 is a schematic cross-sectional diagram illustrating a display device using a semiconductor light emitting device according to a second embodiment of the present disclosure.

Referring to FIG. 10, a pixel structure 100 and a color conversion layer 160 are mainly illustrated.

A display device according to a second embodiment of the present disclosure may constitute the pixel structure 100 including a substrate 150, a partition wall 110 defining a plurality of hexagonal unit pixel areas 102, 103, and 104 on the substrate 150, and a light emitting device 120 installed in each of the unit pixel areas 102, 103, and 104.

That is, the unit pixel areas 102, 103, and 104 may include a red pixel area 102, a green pixel area 103, and a blue pixel area 104. The light emitting device 120 may be a semiconductor Light Emitting Diode (LED). Blue light emitting devices 121, 122, and 123 may be installed in the unit pixel areas 102, 103, and 104, respectively.

The pixel structure 100 of the display device according to the second embodiment may be substantially the same as the pixel structure 100 of the display device according to the first embodiment described with reference to FIG. 2. Hereinafter, the redundant description will be omitted.

The color conversion layer 160 for converting lights emitted from the light emitting devices 121, 122, and 123 into colors corresponding to the unit pixel areas 102, 103, and 104 may be provided on the unit pixel areas 102, 103, and 104, respectively.

In an exemplary embodiment, the color conversion layer 160 may be disposed on the partition wall 110 at a predetermined distance from the semiconductor light emitting devices 121, 122, and 123. That is, the color conversion layer 160 may be disposed as a layer on an upper portion of the partition wall 110.

The color conversion layer 160 may include color conversion parts 161, 162, and 163 corresponding to the unit pixel areas 102, 103, and 104, respectively.

For example, a red color conversion part 161 may be located on the red pixel area 102, and a green color conversion part 162 may be disposed on the green pixel area 103. Meanwhile, a light diffusion part 163 may be provided on the blue pixel area 104. The light diffusion part 163 may also be a kind of color conversion part. That is, the color conversion parts 161, 162, and 163 may be disposed on the unit pixel areas 102, 103, and 104, respectively.

In an exemplary embodiment, the red color conversion part 161 may include a red inorganic phosphor or a red Quantum Dot (QD) that converts blue light corresponding to a wavelength of 400 to 480 nm to a main wavelength band of 600 to 750 nm.

In an exemplary embodiment, the green color conversion part 162 may include a green inorganic phosphor or a green Quantum Dot (QD) that converts blue light corresponding to a wavelength of 400 to 480 nm to a main wavelength band of 490 to 600 nm.

In an exemplary embodiment, the light diffusion part 163 may include a metal oxide, for example, TiO₂.

In this case, the color conversion parts 161, 162, and 163 may be positioned to cover the unit pixel areas defined by the partition wall 110, respectively.

Other descriptions may be substantially the same as those of the display device according to the first embodiment described with reference to FIG. 2. Therefore, redundant descriptions will be omitted.

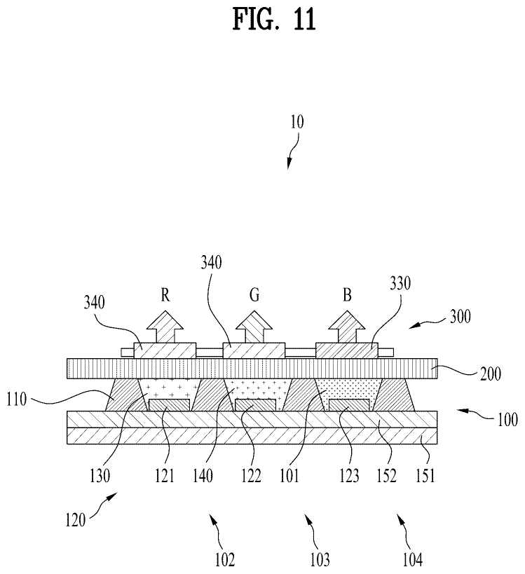

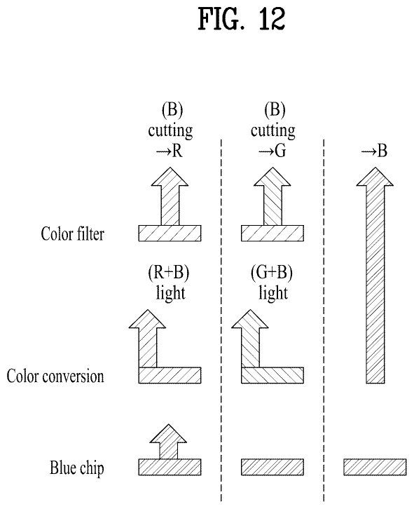

FIG. 11 is a schematic cross-sectional diagram illustrating a display device using a semiconductor light emitting device according to a third embodiment of the present disclosure. FIG. 12 is a conceptual diagram illustrating a light conversion process of a display device using a semiconductor light emitting device according to a third embodiment of the present disclosure.

A display device 10 according to a third embodiment of the present disclosure may constitute a pixel structure 100 including a substrate 150, a partition wall 110 defining a plurality of hexagonal unit pixel areas 102, 103, and 104 on the substrate 150, and a light emitting device 120 installed in each of the unit pixel areas 102, 103, and 104.

The pixel structure 100 may be substantially the same as the display device 10 according to the first embodiment described with reference to FIG. 2. Therefore, the description of the first embodiment may be equally applied to a portion that is not separately described herein.

The unit pixel areas 102, 103, and 104 may include a red pixel area 102, a green pixel area 103, and a blue pixel area 104. The light emitting device 120 may include a semiconductor Light Emitting Diode (LED).

A light emitting device 120 emitting blue light or ultraviolet light may be installed in each of the unit pixel areas 102, 103, and 104. For example, blue light emitting devices 121, 122, and 123 may be installed in the unit pixel areas 102, 103, and 104, respectively. Color conversion layers 130, 140, and 101 may be positioned on the blue light emitting devices 121, 122, and 123 to be converted to colors corresponding to the unit pixel areas 102, 103, and 104, respectively.

As described above, the display device 10 may include the light emitting devices 120 (i.e., 121, 122, and 123) installed in the unit pixel areas 102, 103, and 104, respectively, to form each unit pixel.

Here, the substrate 150 may include a wiring substrate on which a wiring electrode (not shown) is arranged. In this case, each of the light emitting devices 121, 122, and 123 may be electrically connected to the wiring electrode. In addition, each of the light emitting devices 121, 122, and 123 may be electrically connected to a common electrode to be turned on by a current/voltage applied through the wiring electrode and the common electrode.

A Thin Film Transistor (TFT) may be connected to the wiring electrode to implement an Active Matrix (AM) type display device 10. For example, the substrate 150 may include a TFT substrate 152 on a base substrate 151. As another example, the substrate 150 may be a Passive Matrix (PM) type substrate.

The description of the substrate 150 described herein may be equally applied to the first and second embodiments described above.

Color conversion layers 130, 140, and 101 may be provided in the unit pixel areas 102, 103, and 104 to convert lights emitted from the light emitting devices 121, 122, and 123 into colors corresponding to the unit pixel areas 102, 103, and 104, respectively.

For example, a red color conversion layer 130 may be located in a red pixel area 102, and a green color conversion layer 140 may be located in a green pixel area 103. Meanwhile, a light diffusing agent 101 may be provided in a blue pixel area 104. The light diffusing agent 101 may also be a kind of color conversion layer. That is, the color conversion layers 130, 140, and 101 may be located in the unit pixel areas 102, 103, and 104, respectively.

In the present embodiment, similar to the embodiment of FIG. 1, the color conversion layers 130, 140, and 101 are filled in the unit pixel areas 102, 103, and 104, respectively. For example, the color conversion layers 130, 140, and 101 may cover the semiconductor light emitting devices 121, 122, and 123 in the unit pixel areas 102, 103, and 104 partitioned by the partition wall 110, respectively.

A porous layer 200 having a plurality of through-holes may be disposed on the partition wall 110 defining the unit pixel areas 102, 103, and 104.

The porous layer 200 may prevent mixing of lights emitted from the unit pixel areas 102, 103, and 104. That is, the porous layer 200 may prevent crosstalk, which is a phenomenon in which light emitted from a neighboring unit pixel area is mixed with each other.

A color filter layer 300 may be disposed on the porous layer 200. The color filter layer 300 may improve color purity of light emitted from each of the unit pixel areas 102, 103, and 104.

In an exemplary embodiment, the color filter layer 300 may include a yellow filter 340 corresponding to a region of a portion of a unit pixel area. The yellow filter 340 may be disposed on the red pixel area 102 and the green pixel area 103 among the unit pixel areas 102, 103, and 104. A blue color filter 330 may be disposed on the blue pixel area 104.

In an exemplary embodiment, the yellow filter 340 may include a yellow inorganic phosphor or a yellow Quantum Dot (QD) that converts blue light corresponding to a wavelength of 400 to 480 nm to a main wavelength band of 570 to 630 nm.

As another example, the yellow filter 340 may include a yellow dye (pigment). The yellow dye may use at least one of monoazo-based, pyrazolone azo-based, diazo-based, azomethine-based, anthraquinone-based, isoindolinone-based, quinoline-based, quinophthalone-based, polycyclic-based, dioxime-based, benzimidazolone-based, heterocyclic-based, ferrion-based, inorganic, and cyanine-based pigments.

The yellow filter 340 may be a color filter that transmits red light and green light but cuts blue light.

That is, referring to FIG. 12, the color-converted light in the red pixel area 102 may include red light and blue light (R+B). In this case, the yellow filter 340 of the color filter layer 300 may transmit red light and cut blue light (B cutting), thereby improving color purity of red light.

Similarly, the color-converted light in the green pixel area 103 may include green light and blue light (G+B). In this case, the yellow filter 340 of the color filter layer 300 may transmit green light and cut blue light (B cutting), thereby improving the color purity of green light.

The above description is merely illustrative of the technical idea of the present disclosure. Those of ordinary skill in the art to which the present disclosure pertains will be able to make various modifications and variations without departing from the essential characteristics of the present disclosure.

Therefore, embodiments disclosed in the present disclosure are not intended to limit the technical idea of the present disclosure, but to describe, and the scope of the technical idea of the present disclosure is not limited by such embodiments.

The scope of protection of the present disclosure should be interpreted by the claims below, and all technical ideas within the scope equivalent thereto should be construed as being included in the scope of the present disclosure.

### INDUSTRIAL APPLICABILITY

According to the present disclosure, a display device using a semiconductor light emitting device such as a micro LED may be provided.

What is claimed is:

1. A display device, comprising:
a substrate;
a partition wall located on the substrate and defining a plurality of hexagonal unit pixel areas to form a honeycomb shape;
a semiconductor light emitting device located in each of the unit pixel areas to form each unit pixel;
a color conversion layer converting light emitted from the semiconductor light emitting device into a color corresponding to each of the unit pixel areas;
a porous layer located on the partition wall and having a plurality of through-holes; and
a color filter layer located on the porous layer.

2. The display device of claim 1, wherein each of the unit pixel areas is partitioned by the partition wall to have a predetermined region.

3. The display device of claim 2, wherein the color conversion layer is located in the partitioned unit pixel area.

4. The display device of claim 1, wherein the color conversion layer is located at a predetermined distance from the semiconductor light emitting device on the partition wall.

5. The display device of claim 1, wherein the partition wall acts as a black matrix.

6. The display device of claim 1, wherein the porous layer prevents lights emitted from the unit pixel areas from being mixed.

7. The display device of claim 1, wherein the through-hole of the porous layer is formed in a direction of connecting the unit pixel area and the color filter.

8. The display device of claim 1, wherein the porous layer comprises an Anodized Aluminum Oxide (AAO) layer.

9. The display device of claim 1, wherein the color filter layer comprises a color filter corresponding to a color of each of the unit pixel areas.

10. The display device of claim 1, wherein the color filter layer comprises a yellow filter corresponding to a region of a color of part of the unit pixel areas.

11. The display device of claim 10, wherein the yellow filter is located on a red pixel area and a green pixel area among the unit pixel areas.

12. A display device, comprising:
a wiring substrate;
a partition wall located on the substrate and defining a plurality of hexagonal unit pixel areas;
a semiconductor light emitting device located in each of the unit pixel areas to form each unit pixel;
a porous layer located on the partition wall to prevent mixing of lights emitted from the unit pixel areas;
a color conversion layer located between the partition wall and the porous layer to convert the light emitted from the semiconductor light emitting device to a color corresponding to each of the unit pixel areas; and
a color filter layer located on the porous layer.

13. The display device of claim 12, wherein the porous layer comprises a plurality of through-holes formed in a direction of connecting the unit pixel area and the color filter.

14. The display device of claim 12, wherein a plurality of the hexagonal unit pixel areas form a honeycomb shape.

15. The display device of claim 12, wherein each of the unit pixel areas is partitioned by the partition wall to have a predetermined region.

16. The display device of claim 15, wherein the color conversion layer is located in the partitioned unit pixel area.

17. The display device of claim 12, wherein the partition wall acts as a black matrix.

18. The display device of claim 12, wherein the porous layer comprises an Anodized Aluminum Oxide (AAO) layer.

19. The display device of claim 12, wherein the color filter layer comprises a color filter corresponding to a color of each of the unit pixel areas.

20. The display device of claim 12, wherein the color filter layer comprises a yellow filter corresponding to a region of a color of part of the unit pixel areas.
